(19) United States
(12) Patent Application Publication
(10) Pub. No.: US 2010/0127201 A1
(43) Pub. Date: May 27, 2010

(54) INTERLOCKING VALVE CHAMBER AND LID

(75) Inventor: HANS PETER THEODORUS CEELEN, Rio Vista, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/276,146

(22) Filed: Nov. 21, 2008

(51) Int. Cl. F16K 27/00

(52) U.S. Cl. 251/366

(57) ABSTRACT

An apparatus for isolating two regions at different pressures is provided, comprising a chamber having a floor, an open top face, and side walls having at least two apertures opposite one another. The chamber further comprises a dividing plate disposed within the chamber, wherein the dividing plate is attached with the floor and the side walls of the chamber, and wherein the dividing plate has at least one opening opposite each aperture and the dividing plate forms a first region and a second region within the chamber. The chamber also includes a lid comprising a plate, wherein a bottom surface of the plate is configured to couple with the dividing plate when the lid is placed on the top face of the chamber so as to prevent deflection of the dividing plate, and wherein the lid closes the top face of the chamber when placed thereon.

### BACKGROUND OF THE INVENTION

1. Field of the Invention

Embodiments of the present invention generally relate to apparatus for sealing a first region from a second region, and more specifically to techniques for forming a seal between regions of different pressures.

2. Description of the Related Art

Certain process applications require isolation valves that can form an effective seal between a chamber at a certain pressure and an adjacent chamber at a different pressure. For example, in glass substrate processing systems, efficient production line processing requires rapid movement of glass substrates from one work station to another, and between vacuum environments and atmospheric environments. Processing of glass substrates in process chambers is typically performed in a vacuum or under low pressure. Movement of glass substrates between processing chambers, thus, requires the use of valve mechanisms which are capable of effectively closing the especially wide apertures to provide vacuum-tight seals while minimizing contamination between chambers.

In the past, a variety of isolation valves have been used to isolate two regions from one another. One exemplary construction of an isolation valve employs a slit valve having an internal dividing wall or plate within the valve chamber separating the two regions, the valve having a slit or opening to allow passage of the substrate from one region to the other. To close the valve, a gate or door may then slide over the internal wall to cover the slit, thereby forming a seal to prevent flow through the valve.

Oftentimes, the valve chamber will have a removable lid that allows access to the valve chamber for maintenance. Certain problems, however, are associated with using this particular configuration of valve chamber having a removable service access lid. In this configuration, the internal dividing wall may only be attached to the floor and sides of the chamber, such as by welding. The lower portion of the dividing wall will tend to resist deflection, while the upper portion of the wall will not be similarly constrained, and can deflect a considerable amount. Because the two regions of the valve chamber at either side of the internal dividing wall are at different pressures, and the internal dividing wall is typically held in place only along the bottom and side edges, with the top edge lacking structural support, the differential pressure between the two regions will tend to deflect the dividing wall, causing the seal in the gate to fail. Typically, the larger the valve chamber, such as those used for processing large glass substrates, the greater the deflection of the internal dividing wall. For example, when the dividing wall is about 196 inches long by about 28 inches wide with a maximum thickness of about 4 inches and the deflecting force across the dividing wall is 8,200 pounds, the deflection of the internal dividing wall may be as much as 0.5 inches along the axis perpendicular to the face of the dividing wall.

In the past, the deflection problem encountered when using an internal dividing wall in a valve chamber with a removable lid has been remedied by increasing the thickness of the internal dividing wall. However, for larger valve chambers, this approach results in impractical, extraordinarily thick dividing walls and an increased cost of manufacturing the valve. Another remedy has been to attach beam sections to the internal wall for added support. However, this approach results in unserviceable valve chambers.

Therefore, there is a need for a mechanism that will reduce the deflection of the internal dividing wall in a valve chamber with a removable lid separating two regions under different pressures.

### SUMMARY OF THE INVENTION

The present invention generally relates to apparatus for sealing a first region from a second region, and more specifically to techniques for forming a seal between regions of different pressures. In one embodiment, a valve chamber for isolating two regions at different pressures is provided, comprising a chamber having a floor, an open top face, and side walls having at least two apertures opposite one another, a dividing plate disposed within the chamber, wherein the dividing plate is attached with the floor and the side walls of the chamber, and wherein the dividing plate has at least one opening opposite each aperture and the dividing plate forms a first region and a second region within the chamber, and a lid comprising a plate, wherein a bottom surface of the plate is configured to couple with the dividing plate when the lid is placed on the top face of the chamber and wherein the lid closes the top face of the chamber when placed thereon.

In one aspect, the valve chamber further comprises grooves and an elastomeric sealing member on upward facing surfaces of the side walls and the dividing plate. In another embodiment, the elastomeric sealing member comprises at least one O-ring. In yet another embodiment, the at least one opening has a generally oblong shape. In another embodiment, the lid further comprises side walls attached with a top surface opposite the bottom surface of the plate so as to form a box-like structure. In a further embodiment, the first region of the valve chamber operates at a first pressure and the second region operates at a second pressure different from the first pressure.

In another embodiment, the dividing plate further comprises at least one interlocking pin protruding from an upward facing surface of the dividing plate and the lid further comprises an opening to receive the at least one interlocking pin when the lid is placed on the top face of the chamber.

In yet another embodiment, the lid further comprises at least one interlocking pin protruding from a bottom surface of the plate of the removable lid, and the dividing plate further comprises an opening on the upward facing surface of the dividing plate to receive the interlocking pin when the lid is placed on the top face of the chamber.

In another embodiment, the plate of the removable lid is bolted to the dividing plate after the lid is placed on the top face of the chamber.

In yet another embodiment, the lid further comprises at least one bar disposed on a bottom surface of the plate and the dividing plate further comprises at least one notch for receiving the at least one bar when the lid is placed on the top face of the chamber.

In one embodiment, a valve chamber for isolating two regions at different pressures is provided, comprising a chamber having a floor, an open top face, and side walls having at least two apertures opposite one another, a dividing plate disposed within the chamber, wherein the dividing plate is attached with the floor and the side walls of the chamber, wherein the dividing plate has at least one opening opposite each aperture and the dividing plate forms a first region and a second region within the chamber, and a lid comprising a plate having at least one pair of parallel bars attached with a bottom surface of the plate, wherein the bars define a notch for receiving a top edge of the dividing plate when the lid is placed on the top face of the chamber and wherein the lid closes the top face of the chamber when placed thereon.

In another embodiment, a slit valve for isolating two regions at different pressures is provided, comprising a chamber having a floor, an open top face, and side walls having at least two apertures opposite one another, a dividing plate disposed within the chamber, wherein the dividing plate is attached with the floor and the side walls of the chamber, and wherein the dividing plate has at least one opening opposite each aperture and the dividing plate forms a first region and a second region within the chamber, and a lid comprising a plate, wherein a bottom surface of the plate is configured to couple with the dividing plate when the lid is placed on the top face of the chamber and wherein the lid closes the top face of the chamber when placed thereon. The chamber further comprises at least one gate, wherein the gate can be positioned between a closed position over a first surface of the dividing plate so as to cover the at least one opening and seal the first region from the second region, and an opened position wherein the first and second regions are in communication through the at least one opening. In another embodiment, the first region has a higher operating pressure than the second region. In another embodiment, the first surface faces the first region. In yet another embodiment, the slit valve further comprises at least one second gate, wherein the second gate can be positioned in a closed position over a second surface of the dividing plate opposite the first surface so as to cover the at least one opening and seal the first region from the second region, and an opened position wherein the at least one opening is uncovered at the second surface.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a partial longitudinal elevated view of a valve chamber, with the interlocking lid suspended above it, shown in open configuration, according to one embodiment of the present invention.

FIG. 2 is a partial elevated cross-sectional view of the valve chamber of FIG. 1, with the interlocking lid suspended above the valve chamber, shown in open configuration.

FIG. 3 is a partial elevated cross-sectional view of the valve of FIG. 2, with the interlocking lid placed on the valve chamber, shown in open configuration.

FIG. 4 is cross-sectional view of one embodiment of the interlocking valve chamber and lid, shown in closed configuration.

It is contemplated that elements disclosed in one embodiment may be beneficially utilized on other embodiments without specific recitation.

### DETAILED DESCRIPTION

Embodiments of the present invention provide an interlocking valve chamber and lid, wherein the lid is configured to couple with an internal dividing plate inside the chamber so as to prevent a slit valve door or gate from being moved away from a slit valve opening in the internal dividing plate due to deflection of the plate caused by differential pressure across the dividing plate. In one embodiment, the coupling or support mechanism may include al least two bars attached in parallel to the bottom of the lid at a certain distance apart so as to fit on either side of the upper edge of the dividing plate once the lid is placed on the chamber. In another embodiment, the lid may be coupled with the internal dividing plate by bolting the lid to the internal dividing plate. In yet another embodiment, the lid may be coupled with the internal dividing plate using at least one interlocking pin on the lid and at least one corresponding opening in the internal dividing plate, or at least one interlocking pin on the internal dividing plate and at least one corresponding opening in the lid. In another embodiment, the lid may comprise a bar disposed on a bottom surface of the plate and the dividing plate may comprise a notch for receiving the bar when the lid is placed on the top face of the chamber. The support mechanism or method of coupling the lid with the internal dividing plate is not limited to such embodiments.

The coupling or support mechanism reduces deflection of the dividing plate, thereby ensuring that the gate remains sealed. In general, the valve can be used, for example, to isolate one process chamber from another process chamber, or to isolate different regions from one another. Although some of the embodiments refer to the interlocking valve chamber and lid in the context of a substrate processing chamber, the interlocking valve chamber and lid can be used in any similar vessel design that experiences a significant pressure differential and includes a removable service access lid.

In one embodiment, a valve chamber for isolating two regions at different pressures is provided comprising a chamber having a floor, an open top face, and side walls having at least two apertures opposite one another. The chamber further comprises a dividing plate disposed within the chamber, wherein the dividing plate is attached with the floor and the side walls of the chamber, and wherein the dividing plate has at least one opening opposite each aperture and the dividing plate forms a first region and a second region within the chamber. The chamber further includes a lid comprising a plate, wherein a bottom surface of the plate is configured to couple with the dividing plate when the lid is placed on the top face of the chamber. The lid closes the top face of the chamber when placed thereon.

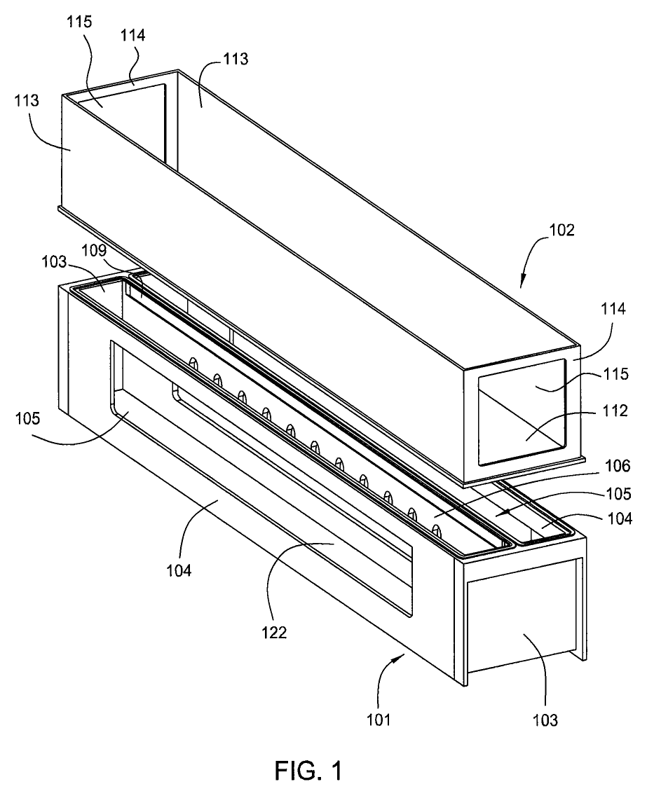

FIG. 1 is a perspective view of one embodiment of an interlocking valve chamber and lid, with a lid 102 suspended above a valve chamber 101, shown in open configuration (actual valve not shown). The valve chamber may comprise sidewalls and a floor. In one embodiment, as shown in FIG. 1, the valve chamber 101 comprises a floor or bottom wall 122, a first pair of opposite and parallel side walls 103, and a second pair of opposite and parallel side walls 104 to form a box-like structure with an open top face. In another embodiment, the valve chamber may comprise sidewalls and a floor to form a circular or elliptical box-like structure. As shown in FIG. 1, side walls 104 may overhang floor 122 and side walls 103. Side walls 104 may each contain at least two apertures 105. The at least two apertures 105 may be opposite one another. In an alternative embodiment, side walls 104 may comprise four apertures, with one pair of apertures opposite the other. Apertures 105 are sized and adapted to allow for the transfer of an object, such as a glass substrate, through valve chamber 101. The object may enter the chamber through at least one aperture on a side wall at one end of the chamber and exit the chamber through at least one aperture on a side wall at the opposite end of the chamber. Valve chamber 101 may be made of aluminum or stainless steel, or another material or combination or materials, depending on the application.

Valve chamber 101 may also comprise a dividing wall or plate 106 disposed inside of chamber 101 and attached with the floor and the sidewalls of the chamber. As shown in FIG. 1, in one embodiment, dividing plate 106 may be disposed in between and parallel to the second pair of side walls 104. In one embodiment, the dividing plate 106 may be attached with the floor 122 and side walls 103 by welding. The dividing plate 106 may be attached with the floor 122 and the first pair of side walls 103 to form a first region and a second region within the valve chamber 101. In one embodiment, the first region and the second region may have different operating pressures. In one example, the first region may have a higher operating pressure than the second region. For example, in one embodiment, the first region may operate under atmospheric pressure, whereas the second region may operate under vacuum conditions. In another embodiment, the second region may have a higher operating pressure than the first region.

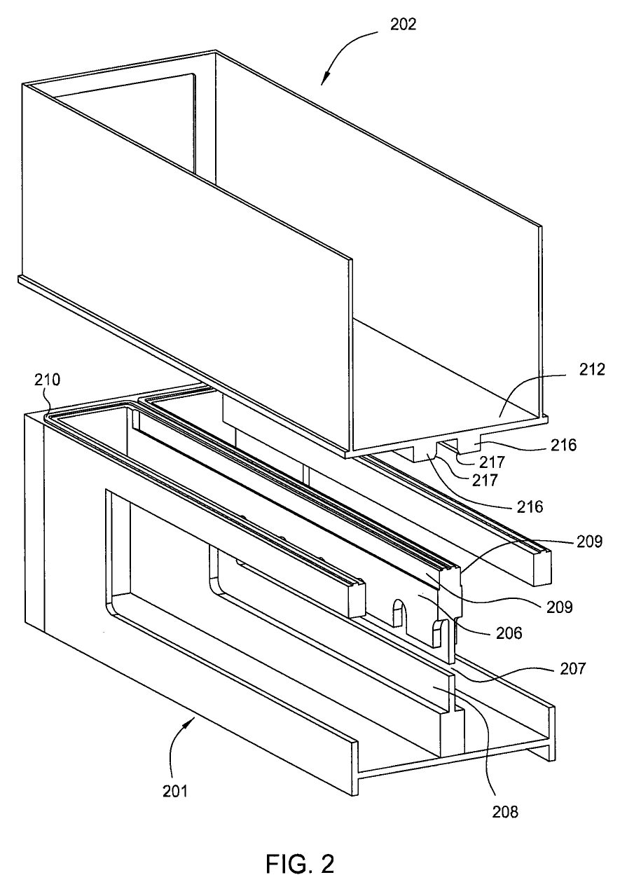

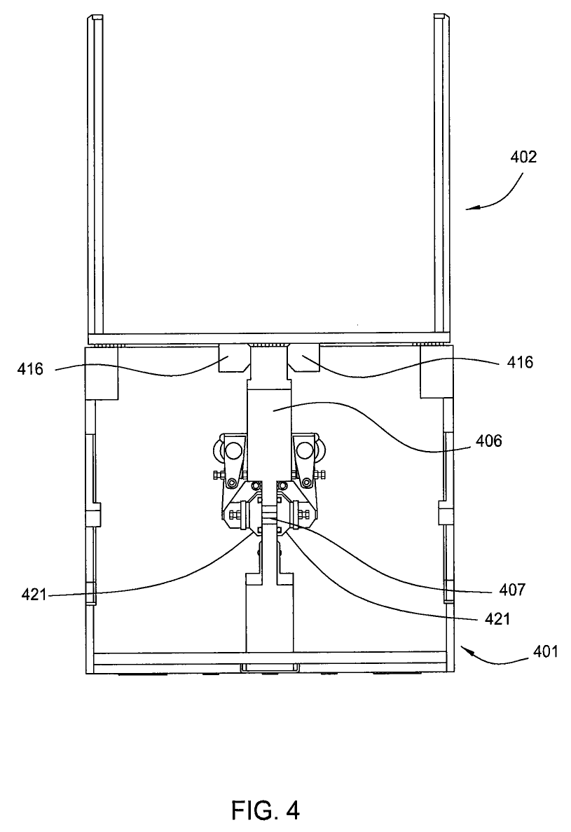

The dividing plate 106 may comprise at least one opening 207 (not shown in FIG. 1; see FIG. 2) opposite the apertures 105. FIG. 2 is a partial elevated cross-sectional view of the interlocking valve chamber and lid of FIG. 1, with the interlocking lid suspended above the box chamber, shown in open configuration. Opening 207 may be sized and adapted to allow passage of an object from a first region of valve chamber 202 to a second region of valve chamber 202. In one embodiment, opening 207 may be long enough and wide enough to allow for the passage of a large glass substrate. For example, opening 207 may be 3 meters long by 45 millimeters wide. Opening 207 may be oblong, or rectangular in shape, or elliptical, or have a rectangular shape with rounded corners. In one embodiment, opening 207 may be formed within a recess 208 in dividing plate 206 of a certain depth and shape. The recess 208 may be formed on one or both interior surfaces or sides of plate 206. Recess 208 may move valve gates 421 (see FIG. 4) closer together to minimize distance between conveyor rolls (not shown) on either side of valve gates 421.

In one embodiment, as shown in FIG. 1, at least one groove or recess 109 may be formed along a length of an upper edge of each side of the dividing plate 106. FIG. 2 shows two grooves or recesses 209 formed on either side of dividing plate 206, in accordance with one embodiment. In one example, groove 109 may be formed over the entire length of dividing plate 106. In another example, groove 109 may be formed over less than the entire length of dividing plate 106. Groove 109 may have a certain depth, in a direction along the thickness of the dividing plate 106, depending on the application. As shown in FIG. 2, groove 209 may also have a width extending further down the dividing plate 206, towards the opening 207, depending on the size of the dividing plate and the amount of deflection sought to be avoided. Grooves 209 may have rounded edges, sharp edges, or a combination thereof.

As shown in FIG. 1, lid 102 may comprise a plate that fits over chamber 101 so as to fully cover the open top face of chamber 101. Lid 102 may be rectangular in shape. However, lid 102 is not limited to a rectangular shape so long as lid 102 covers the open top face of chamber 101 when placed thereon. In one embodiment, lid 102 may have an open box-like shape or structure with a floor and sidewalls. The box-like shape or structure may be a rectangular box or a circular or elliptical box, or a box of a different shape having a generally open top face. As shown in FIG. 1, in one embodiment, lid 102 may have an open box-like shape or structure with a floor 112 and two pairs of opposite and parallel side walls 113 and 114 perpendicular to floor 112. In one embodiment, one pair of sidewalls 114 may comprise apertures 115. Apertures 115 can allow access to lid 102 components for maintenance. Lid 102 may be lowered over valve chamber 101 so that floor 112 is disposed over the top face of valve chamber 101, thereby further enclosing valve chamber 101. In one embodiment, as shown in FIG. 1, lid 102 is placed over valve chamber 101 such that side walls 113 are located above and parallel to side walls 104 of the valve chamber 101 and side walls 114 are located above and parallel to side walls 103 of the valve chamber 101. In one example, floor 112 of lid 102 may be larger than the area defined by side walls 113 and 114 so that it forms a ledge at the bottom of lid 102, as shown in FIG. 1.

FIG. 2 is a cross-sectional partial side and front perspective of the interlocking valve chamber and lid in FIG. 1, showing lid 202 suspended above valve chamber 201 (actual valve not shown). As shown in FIG. 2, lid 202 may comprise two bars 216 disposed longitudinally and parallel to each other on a bottom surface of floor 212 of lid 202. Bars 216 may be set apart from each other a certain distance that should generally correspond to the thickness of the upper edge of dividing plate 206. The bars 216 may form a notch for receiving the upper edge of dividing plate 206 when lid 202 is placed on chamber 201. In one aspect, bars 216 may be set apart from each other at a certain distance that should generally correspond to the thickness at the location of grooves or recesses 209 on dividing plate 206. In one embodiment, the grooves or recesses 209 may be a machined surface of a controlled width that fits with minimum clearance between bars 216 in order to obtain a close fit when lid 202 is placed on the open top face of chamber 201. Minimizing clearance between bars 216 and the grooves or recesses 209 of the dividing plate 206 will limit the free deflection of the dividing plate 206. Bars 216 may be made of aluminum or stainless steel, or another material or combination of materials, depending on the application. In one embodiment, bars 216 may be welded onto the bottom surface of floor 212 of lid 202. In another embodiment, bars 216 may be bolted onto the bottom surface of floor 212 of lid 202. In another embodiment, bars 216 and floor 212 of lid 202 may be machined from a single piece of material. In one embodiment, as shown in FIG. 2, bars 216 may have inside longitudinal corners 217 tapered or cut at an angle so as to facilitate mating of the lid 202 with the valve chamber 201.

In another embodiment, instead of having just two bars on the bottom surface of floor 212 of lid 202, two pairs of parallel bars may be disposed longitudinally and in line on a bottom surface of floor 212 of lid 202, wherein the pairs of bars are positioned so that they may receive the upper edge of the dividing plate 206 when the lid 202 is placed on the valve chamber 201. In another embodiment, there may be three, or four, or more pairs of bars disposed longitudinally and in line on a bottom surface of floor 212 of lid 202 to engage the upper edge of the dividing plate 206 when the lid 202 is placed on the valve chamber 201.

In one embodiment, bars 216 may have a height in a direction away from floor 212 corresponding to the width of grooves 209, so that bars 216 cover the entirety of grooves 209 when lid 202 is placed over valve chamber 201. In another embodiment, bars 216 may have a height in a direction away from floor 212 which is smaller than the width of grooves 209, so that a portion of the width of grooves 209 remains exposed to the inside of chamber 201 when lid 202 is placed over valve chamber 201 (i.e. the bars 216 do not completely cover grooves 209).

In order to prepare valve chamber 201 for use, such as after maintenance, lid 202 will be lowered upon the top of valve chamber 201 so that bars 216 engage into grooves 209 causing lid 202 and valve chamber 201 to interlock, whereby each bar 216 is disposed on either side of and adjacent to a top portion of dividing plate 206 having grooves 209. Lid 202 may be lowered onto chamber 201 using a crane, depending on the size and weight of lid 202.

In one embodiment, valve chamber 201 may comprise grooves 210 along upward facing edges of the chamber side walls and the dividing plate 206. In yet another embodiment, these grooves may further comprise an elastomeric seal, such as an O-ring, to form a seal between valve chamber 201 and lid 202.

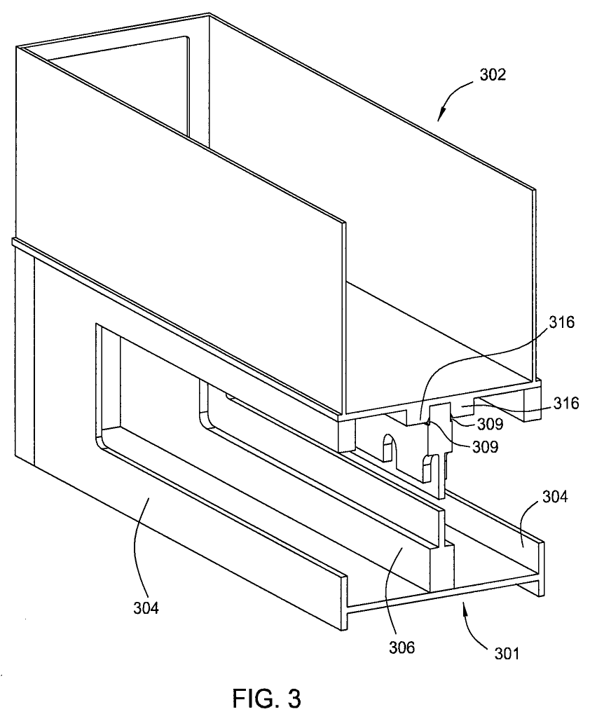

FIG. 3 is a partial elevated cross-sectional view of the embodiment of the interlocking valve chamber and lid of FIG. 2, with lid 302 placed on valve chamber 301, shown in open configuration (actual valve not shown). In one embodiment, as shown in FIG. 3, bars 316 may have a width larger than the depth of grooves 309 so that bars 316 extend outward beyond grooves 309 in a direction towards side walls 304 when lid 302 is placed over valve chamber 301 (i.e. outer vertical surfaces of bars 306 will not be flush with the vertical surfaces of dividing plate 306 when lid 302 is placed over valve chamber 301).

In one embodiment, bars 316 may extend the entire length of grooves 309. Preferably, bars 316 will be of a sufficient length, height and width so as to prevent deflection of dividing plate 306 under chamber operating conditions by transferring some of the deflecting forces to lid 302. In one embodiment, the width and height of bars 316 may be increased in order to achieve a greater degree of engagement between valve chamber 301 and lid 302.

As shown in FIG. 4, valve chamber 401 may comprise a maintenance valve 421 attached to dividing plate 406 that seals opening 407 from either side when it is in a closed configuration (as shown in FIG. 4). It should be noted that different types of valves may be used in conjunction with the interlocking valve chamber and lid. The maintenance valve shown in FIG. 4 is an example of a type of valve which can be used to form the seal between the two chamber regions defined by the dividing plate 406.

After, for example, a glass substrate has passed through the valve chamber 401, maintenance valves 421 may radially swing down onto each side of the dividing plate from an open position to a closed position so as to cover opening 407 (see FIG. 4). Alternatively, after the substrate has passed through the valve chamber 401, a valve may radially swing down onto the surface of the dividing plate 406 facing the chamber region of higher operating pressure so as to cover opening 407, isolating the regions on either side of dividing plate 406.

In one example, the region on one side of the dividing plate 406 will be at atmospheric pressure, or about 15 psi, while the region on the other side of the dividing plate 406 will be under vacuum, or 0 psi. The bars 416 on the lid 402 which interlock with the internal dividing plate 406 will help transfer deflection forces caused by the pressure differential to the lid 402 so as to reduce deflection of the dividing plate 406 and prevent valve leaks.

The coupling of the lid with the dividing plate may also be achieved with apparatus other than parallel bars disposed on the lid. In one embodiment, the dividing plate may comprise at least one interlocking pin protruding from an upward facing surface of the dividing plate and the lid may comprise at least one opening to receive the at least one interlocking pin when the lid is placed on a top face of the chamber. In another embodiment, the lid comprises at least one interlocking pin protruding from a bottom surface of the plate of the removable lid, and the dividing plate comprises at least one opening on the upward facing surface of the dividing plate to receive the interlocking pin when the lid is placed on the top face of the chamber. In yet another embodiment, the plate of the removable lid may be bolted to the dividing plate after the lid is placed on the top face of the chamber.

In another embodiment, the lid may comprise at least one bar disposed on a bottom surface of the plate and the dividing plate may comprise at least one notch for receiving the at least one bar when the lid is placed on the top face of the chamber. The notch may run lengthwise along the top surface of the dividing plate. The bar may be wide enough and deep enough to provide sufficient support for the dividing plate when the lid is placed on the top face of the chamber to prevent deflection of the dividing plate along an axis perpendicular to the face of the dividing plate.

Although the invention has been described in accordance with certain embodiments and examples, the invention is not meant to be limited thereto. For instance, although some of the embodiments referred to herein describe the use of the interlocking valve chamber and lid in a glass substrate processing chamber, it should be appreciated that the interlocking valve chamber and lid can be used in any similar vessel design that experiences a significant pressure differential and requires a removable service access lid. Also, although some of the embodiments referred to herein describe certain apparatus for coupling the lid with the dividing plate inside the valve chamber, other apparatus may be used to couple the lid with the dividing plate to support the dividing plate and prevent deflection thereof by forces generated during processing.

While the foregoing is directed to embodiments of the present invention, other and further embodiments of the invention may be devised without departing from the basic scope thereof, and the scope thereof is determined by the claims that follow.

1. A valve chamber for isolating two regions at different pressures comprising:
a chamber having a floor, an open top face, and side walls having at least two apertures opposite one another;
a dividing plate disposed within the chamber, wherein the dividing plate is attached with the floor and the side walls of the chamber, and wherein the dividing plate has at least one opening opposite each aperture and the dividing plate forms a first region and a second region within the chamber; and
a lid comprising a plate, wherein a bottom surface of the plate is configured to couple with the dividing plate when the lid is placed on the top face of the chamber and wherein the lid closes the top face of the chamber when placed thereon.

2. The valve chamber of claim 1, further comprising grooves and an elastomeric sealing member on upward facing surfaces of the side walls and the dividing plate.

3. The valve chamber of claim 2, wherein the elastomeric sealing member comprises at least one O-ring.

4. The valve chamber of claim 1, wherein the at least one opening has an oblong shape.

5. The valve chamber of claim 1, wherein the lid further comprises side walls attached with a top surface opposite the bottom surface of the plate so as to form a box-like structure.

6. The valve chamber of claim 1, wherein the first region operates at a first pressure and the second region operates at a second pressure different from the first pressure.

7. The valve chamber of claim 1, wherein the dividing plate further comprises at least one interlocking pin protruding from an upward facing surface of the dividing plate and the lid further comprises at least one opening to receive the at least one interlocking pin when the lid is placed on the top face of the chamber.

8. The valve chamber of claim 1, wherein the lid further comprises at least one interlocking pin protruding from a bottom surface of the plate of the removable lid, and the dividing plate further comprises at least one opening on the upward facing surface of the dividing plate to receive the interlocking pin when the lid is placed on the top face of the chamber.

9. The valve chamber of claim 1, wherein the plate of the removable lid is bolted to the dividing plate after the lid is placed on the top face of the chamber.

10. The valve chamber of claim 1, wherein the lid further comprises at least one bar disposed on a bottom surface of the plate and the dividing plate further comprises at least one notch for receiving the at least one bar when the lid is placed on the top face of the chamber.

11. A valve chamber for isolating two regions at different pressures comprising:
a chamber having a floor, an open top face, and side walls having at least two apertures opposite one another;
a dividing plate disposed within the chamber, wherein the dividing plate is attached with the floor and the side walls of the chamber, wherein the dividing plate has at least one opening opposite each aperture and the dividing plate forms a first region and a second region within the chamber; and
a lid comprising a plate having at least one pair of parallel bars attached with a bottom surface of the plate, wherein the bars define a notch for receiving a top edge of the dividing plate when the lid is placed on the top face of the chamber and wherein the lid closes the top face of the chamber when placed thereon.

12. The valve chamber of claim 11, wherein the dividing plate further comprises at least one recess along a length of each vertical side of the top edge of the dividing plate to receive the bars on the lid.

13. The valve chamber of claim 12, wherein the bars do not completely cover the recesses once the lid is placed on the chamber.

14. The valve chamber of claim 11, further comprising grooves and an elastomeric sealing member on upward facing surfaces of the side walls and the dividing plate.

15. The valve chamber of claim 14, wherein the elastomeric sealing member comprises at least one O-ring.

16. The valve chamber of claim 11, wherein the at least one opening has an oblong shape.

17. The valve chamber of claim 11, wherein the lid further comprises side walls attached with a top surface opposite the bottom surface of the plate so as to form a box-like structure.

18. The valve chamber of claim 11, wherein the first region operates at a first pressure and the second region operates at a second pressure different from the first pressure.

19. A slit valve for isolating two regions at different pressures comprising:
a chamber having a floor, an open top face, and side walls having at least two apertures opposite one another;
a dividing plate disposed within the chamber, wherein the dividing plate is attached with the floor and the side walls of the chamber, and wherein the dividing plate has at least one opening opposite each aperture and the dividing plate forms a first region and a second region within the chamber;
a lid comprising a plate, wherein a bottom surface of the plate is configured to couple with the dividing plate when the lid is placed on the top face of the chamber and wherein the lid closes the top face of the chamber when placed thereon; and
at least one gate, wherein the at least one gate can be positioned between a closed position over a first surface of the dividing plate so as to cover the at least one opening and seal the first region from the second region, and an opened position wherein the first and second regions are in communication through the at least one opening.

20. The slit valve of claim 19, wherein the first region has a higher operating pressure than the second region.

21. The slit valve of claim 20, wherein the first surface faces the first region.

22. The slit valve of claim 19, further comprising at least one second gate, wherein the at least one second gate can be positioned in a closed position over a second surface of the dividing plate opposite the first surface so as to cover the at least one opening and seal the first region from the second region, and an opened position wherein the at least one opening is uncovered at the second surface.
